(19) United States
(12) Patent Application Publication
(10) Pub. No.: US 2023/0421106 A1
(43) Pub. Date: Dec. 28, 2023

(54) Modular Amplifier and Amplifier Assembly Comprising the Same

(71) Applicant: Stem Technologies | iXora Holding B.V., Ede (NL)

(72) Inventor: Vincent Daniël Van Hanxleden Houwert, Ede (NL)

(21) Appl. No.: 18/036,285

(22) PCT Filed: Nov. 10, 2021
(86) PCT No.: PCT/NL2021/050690

§ 371 Date: May 10, 2023

(30) Foreign Application Priority Data
Nov. 12, 2020 (NL) 2026882
Nov. 12, 2020 (NL) 2026883

(51) Int. Cl. H03F 1/02; H03F 1/30; H03F 3/21

(52) U.S. Cl. CPC H03F 1/0277; H03F 1/30; H03F 3/211; H03F 2200/03

(57) ABSTRACT

The present invention is related to a modular amplifier comprising; an amplifier housing, said housing provided with; an amplifier power input connection, at least one amplifier signal input connection for receiving at least one input signal to be amplified, at least one amplifier signal output connection, for delivering at least one amplified signal; a plurality of amplifier modules, each module comprising: a module power connection coupled to the amplifier power input connection; a module signal input connection; a module signal output connection; amplification hardware, having an amplifying power; a controller, configured for: selectively connecting, based on an algorithm, the at least one amplifier signal input connection to one or more module signal input connections of amplifier modules, for amplifying the at least one input signal to be amplified, and connecting the module signal output connection of said one or more amplifier modules to one or more amplifier signal output connections. The invention is further related to an assembly comprising said amplifiers.

The present invention is related to a modular amplifier and an a modular amplifier assembly comprising the modular amplifiers. The present invention is further related to a device and a method for selectively connecting at least one audio input connector with at least one audio output connector. The invention is more in particular further related to selectively connecting audio input connectors that receive amplified analog signals, to audio output connectors that are either directly or indirectly connected to speakers.

Modular amplifier systems are typically known in the art. Systems are known which house a modular number of amplifier units. These amplifier units can typically be inserted into the system, modularly adjusting the total amount of amplifying power available by the system. Each of the amplifier units is packed in an amplifier housing, which is configured to co-act with the amplifier system. Using a common system housing to slide or click in the amplifier units yields a number of beneficial results. First of all it is possible to quickly couple and release the amplifier units, which saves a lot of time compared to the systems which are not modular, and require lots cabling to combine various amplifier units. Secondly, the system can be configured according to the need of the situation. However, the modular amplification system according to the prior art also comes with a disadvantage. The possibilities for using the plurality of separate amplifier units is limited. They can be used as a singular amplifier unit, each for amplifying a signal. This significantly impacts on the possible usage of said system and reduces its benefits to essentially solely the reduction of cabling required.

The goal of the present invention is to provide a modular amplifier system which has more modularization options, or at least provide an alternative to the amplifier system according to the prior art.

The present invention realises this goal by providing a modular amplifier comprising; an amplifier housing, said housing provided with; an amplifier power input connection, at least one amplifier signal input connection for receiving at least one input signal to be amplified, at least one amplifier signal output connection, for delivering at least one amplified signal; a plurality of amplifier modules, each module comprising: a module power connection coupled to the amplifier power input connection; a module signal input connection; a module signal output connection; amplification hardware, having an amplifying power; a controller, configured for: selectively connecting, based on an algorithm, the at least one amplifier signal input connection to one or more module signal input connections of amplifier modules, for amplifying the at least one input signal to be amplified, and connecting the module signal output connection of said one or more amplifier modules to one or more amplifier signal output connections.

As such the present invention allows to modularly utilize an amplifier. That is, the amplifier is able to selectively connect any number of modules, i.e. combine the modules, to the input and output of said amplifier. This means that the amplifier is able to be used for amplifying signals with a varying amplification power, whilst keeping the modules at their optimum efficiency, and utilizing the remaining amplification power for amplifying one or more other signals. According to the art, an amplifier has a total rated amplifying power, which it can use to amplify one single signal, as long as this signal requires an amplification which is below the rated power. As soon as the signal requires an amplification larger than the rated maximum, the amplifier is not able to efficiently amplify said signal. On the other hand, in the case the signal only requires a minimal amplification, the entire amplifier is used. Therefore, in prior art solutions, the utilization of the amplifier is limited. The present invention allows the user to include more variations. By using modules that can be selectively connected to the signal input and output connection of the amplifier, an arbitrary number of amplifying stations can be formed within the amplifier. Also, if a signal at the amplifier signal input only requires a minimum amplification, a single module or a small number of modules combined, can be allocated by the controller and connected to the input connection, such that the single module, or small number of modules combined amplifies said signal. During amplification the modules operate at their maximum efficiency. Furthermore, the remaining unused modules can be used for amplifying another signal, therefore increasing the flexibility of the amplifier according to the invention over the prior art. It is conceivable that the controller automatically and continuously allocates, combines, separates said amplifier modules for correctly amplifying the incoming signal. However, it is furthermore possible to manually allocate a predetermined percentage of the amplifier. That is, a user can configure to utilize a given percentage of the modules in an automatic mode, wherein the controller and/or algorithm automatically configures the modules, and at the same time utilize the remaining percentage of modules in manual operation mode, wherein the user manually assigns a signal to the modules operating in manual mode. It is furthermore possible to completely utilize the amplifier in either automatic or manual mode. The housing of the amplifier is formed out of a shielding material, such that the signals are not disturbed by any outside source, such as high current and/or voltage devices. It is conceivable that the amplifier signal input, output, and power connections are mounted in a mutual connector, such that the entire amplifier is connected using only a single connector. The number of modules can be varied according to the use of the amplifier. In a particular example the amplifier might comprise at least 4 separate modules, preferably 10 separate modules, more preferably at least 12 separate modules. In case the amplifier is used in for example concert venues, larger amplification powers are most likely requested. Therefore the modules can be designed to each amplify at least 500 W, preferably at least 750 W, more preferably at least 1000 W. In case of a different application, such as for example in an office building, lower powers such as 100 W per module are also conceivable. It should be understood that the controller could either be housed inside the amplifier, or can in fact be a stand alone unit, or located inside another assembly, which is able to communicate with the amplifier in order to execute its functionalities. Hence, the controller does not necessarily have to be in the amplifier housing, and can in fact be positioned anywhere as long as it is configured to selectively connect, based on the algorithm, the at least one amplifier signal input connection to one or more module signal input connections of amplifier modules.

In an alternative embodiment according to the present invention the algorithm comprises the step of receiving a requested amplification power related to the at least one input signal to be amplified, monitoring an available amplification power of each module, and wherein the algorithm further comprises the step of determining, based on the requested amplification power and/or available amplification power of each module, if one amplifier module or a combination of amplifier modules has the requested power available. By receiving a requested amplification power, and monitoring the available amplification power the amplifier according to the present invention is able to compare the current situation and predict the most efficient occupation of the modules. This can be furthermore elaborated as follows. If an input signal is currently amplified by one or more modules, the amplifier is able to check, if a higher amplification power becomes required for said signal, whether the one or more modules have power available for satisfying the new request. If this is the case, nothing is changed and the same modules are utilized. However, in case the current modules are not able to provide the new amplification power request, one or more additional modules are utilized for together amplifying the signal according to the new request, such that each module operates at its optimum efficiency. The steps of receiving a requested amplification power related to the at least one input signal, monitoring the available amplification power of each module, and determining whether one or more modules have the requested power available are mentioned together. However, the steps of receiving the request, and monitoring the power can also be implemented separately in every embodiment, and are therefore not limited to this embodiment. It is further conceivable that the algorithm is further configured for selectively connecting the at least one amplifier signal input connection to the module signal input connections of the determined module or combination of modules having the power available, and connecting the module signal output connection of said module or combination of modules to one or more amplifier signal output connections. Doing so ensures that the output of the modules amplifying the at least one signal are combined and connected to the amplifier signal output such that the correct output signal is obtained. Even though it is related to the algorithm, it is also conceivable that the controller is in fact configured for executing this.

In yet an alternative embodiment of the present invention the at least one amplifier signal input connection is configured for simultaneously receiving a plurality of signals to be amplified, or the amplifier comprises a plurality of amplifier signal input connections, each for receiving one signal to be amplified, wherein the controller is further configured for; selectively forming, based on the algorithm, a plurality of one or more amplifier module groups, each for amplifying a signal, forming one or more virtual amplifiers. Since the amplifier according to the present invention is able to combine modules for amplifying signals according to a requested amplification power, it can furthermore be utilized for, as a single amplifier, amplifying more than one signal. That is, out of the number of modules multiple groups, each consisting of one or more modules, are formed. Each of the groups is configured for amplifying a separate signal. Hence, two signals can be amplified simultaneously in the same amplifier. It is furthermore possible that both signals are amplified with different amplification powers. Due to the modular configuration, any combination of signals and amplification powers is possible as long as the combined powers and signals does not exceed the combined amplification power of all modules of the amplifier combined. It is noted that although stated is that the controller is configured for forming one or more amplifier module groups, a single amplifier is considered to be a group as well. Therefore, the maximum number of separate groups, and thus maximum number of signals that the amplifier can simultaneously amplify is equal to the total number of amplifier modules. The virtual amplifier can be contemplated as a sub amplifier formed within the amplifier itself. Hence, the amplifier according to the present invention houses as many virtual amplifiers as the total number of amplifier modules.

In a further embodiment of the amplifier according to the present invention the algorithm comprises the step of; receiving, for each signal, a requested amplification power monitoring an available amplification power of each module, and wherein the algorithm further comprises the step of; determining, based on the requested amplification power and/or available amplification power of each module and each signal, if the one or more amplifier module groups has the requested power available, selectively connecting the at least one amplifier signal input connection to the module signal input connections of the determined one or more amplifier module groups having the power available, and connecting the module signal output connection of said one or more amplifier module groups to one or more amplifier signal output connections. This allows the amplifier according to the present invention utilize the amplifier according to its maximal flexibility. Any number of signals, which is lower than the maximum amount of modules present in the amplifier, can be amplified simultaneously, forming a number of virtual amplifiers. To allow this, the controller and/or algorithm is configured for monitoring requested amplification powers related to the input signals. That is, each input signal has its own amplification request. Monitoring a current power usage of the modules allows to compute the amount of free amplification power that is available. It is thus to be noted that the amplifier can either monitor the power available in each module, or the power used in each module. By using the amplification power requested by each signal, and the available and/or used power in each module, the algorithm and/or controller are able to compute the optimal allocation of modules for all signals. Preferably all modules are operating at optimal efficiency, that is measured in a percentage of load.

In yet another embodiment the controller is further configured for; determining if an actual performance of at least one amplifier module is exceeding a predetermined performance threshold value, if at least one amplifier module is exceeding the threshold value, assigning an additional amplifier module to the signal, such that preferably all amplifier modules assigned to the signal meet the performance threshold value, if all amplifier modules are operating at their performance threshold value, equally dividing the request over all amplifier modules. The performance threshold is used to maintain the amplifier modules at their optimum working efficiency. If one module surpasses said threshold the controller can reallocate the signal to different modules, or the controller can assign an additional controller to assist the current module. In fact, due to the flexibility of the amplifier in assigning modules to signals, the controller can reallocate each signal if necessary. If all of the modules are already occupied, the controller will assign a higher amplification power equally over all modules. In general it can be stated that at the point that all modules are occupied by a signal, no additional signals can be amplified by the amplifier. Meaning that one module can only be used by one signal at a time. However, in the case that all modules are occupied by one or more signals, and an additional signal is received, the controller will send off an error or warning to the user. Measuring the performance threshold values of the modules can always be implemented. That is, in case a single input signal is used, or multiple input signals, or when the amplifier according to the present invention is coupled to other amplifiers.

In a further embodiment the performance threshold value is chosen from the group consisting of; an actual power of a module; a temperature of a module; frequencies available in the signal, however also performance thresholds that are only applicable on a larger scale, such as in an assembly according to the invention, might be used. As such all locations within the assembly might be monitored and power allocated based accordingly. One of such may for example be moisture present inside the system, which could influence the performance of (a part of) the amplifier. Upon detection the controller might distribute the signals differently over available modules. The actual power of a module is to be understood as the actual amplification power used at any time. The modules are preferably utilized at an optimal setting. Such an optimal setting can due to heat generation in the modules in particular be at a maximum load of 100 percent, in particular 90 percent, more in particular at 70 percent, and most particularly at 60 percent. This percentage has turned out to leave room for unexpected peaks. The maximum allowable temperature of the module depends on the components used for said module. The frequencies available in the signal can also be used as a performance threshold. The algorithm and/or controller are configured for analysing an input signal in the frequency spectrum, or if the controller and/or algorithm is configured for recognizing a certain signal, act upon a previous occasion. The signal may comprise for example periods of low volume music, and periods of high volume music, which requires more amplification power. In such cases the amplifier can, in advance, allocate additional modules to a signal to compensate for upcoming amplification power requests. As such, the quality of the music is enhanced.

In yet a different configuration the at least one amplifier signal input connection is configured for; receiving a composed signal, decomposing the received composed said composed signal into a plurality of signals to be amplified. This allows the user to either send digital or analog signals to the amplifier. Yet further it allows the user to send composed signals of digital or analog type to the amplifier. This even further enhances the flexibility of the amplifier.

The present invention is further related to a modular amplifier assembly. Said modular amplifier assembly, comprising; an assembly housing, said housing provided with; at least one assembly signal input, for receiving at least one signal to be amplified, at least one assembly signal output, for delivering at least one amplified signal; a common power unit, for delivering a power to the assembly, a plurality of slots, each slots configured for receiving a modular amplifier according to any of the embodiments, wherein each slot comprising; a power connector, connected to the common power unit on one end and the amplifier power input connection of an inserted amplifier on the other end, for powering the inserted amplifier, a signal input connector, connected to the assembly signal input on one end, and the at least one amplifier signal input connection of an inserted amplifier on the other end, for providing the inserted amplifier with at least a portion of the least one signal to be amplified, a signal output connector, connected to the assembly signal output on one end, and the at least one amplifier signal output of an inserted amplifier on the other end, for delivering an amplified signal, a controller unit, wherein the controller unit is configured for; selectively forming, based on the algorithm, one or more amplifier module groups, wherein said groups are formed out of one or more inserted amplifiers, forming one or more virtual amplifiers, and connecting the one or more amplifier signal output connections to the one or more assembly signal output connections. By using the amplifier assembly according to the present invention the modularization options even further increase. However not only the modularization opportunities are positively affected by the assembly. Also the ease of use is significantly increased. The assembly housing is equipped with a plurality of slots, wherein each slot is configured to receive an amplifier according to the present invention. However, it is also conceivable that the slots are configured for receiving other known amplifiers, such that the user is not restricted to amplifiers according to the present invention. The slots can be configured as slides in a rack, wherein the amplifiers can be easily slid into the assembly. A common back panel may be present, wherein the back panel houses the power connector, the signal input connector and the signal output connector. Said connectors being configured for signally connecting the amplifier to the assembly. The slots may further be equipped with a lock, for locking an amplifier in the assembly after it is slid into the slot and connected with the connectors. The controller unit analyzes the total number of inserted amplifiers, and is configured to selectively form groups of amplifier modules. The groups do not necessarily have to be housed in one amplifier. It might be possible to form a group consisting of a number of modules in a first amplifier, and a number of modules in a second amplifier. That is, said group thus forming a virtual amplifier. The amount of possibilities for combining the modules are only limited by the total amount of modules present in all inserted amplifiers. Furthermore all benefits related to the modular amplifier according any of the embodiments also apply to the assembly according to the present invention, and are hereby included by reference. The common power unit may either receive AC or DC power, however, it is also possible to receive a mixed AC and DC power. The common power unit may receive the power via a connector comprising a plurality of pins. Preferably the required AC and DC power capacity may be offered in a plurality of voltages, preferably 230V AC+24/12/513V DC, preferably all combinations may be provided for via the same connector in the assembly.

In yet another embodiment of the amplifier assembly the controller unit is further configured for receiving a requested amplification power related to the at least one input signal to be amplified, monitoring an available amplification power of each module, and wherein the algorithm comprises the step of determining, based on the requested amplification power and/or available amplification power of each module, if one amplified module or a combination of amplified modules has the requested power available, selectively connecting the at least one amplifier signal input connection to the module signal input connections of the determined module or combination of modules having the power available, and connecting the module signal output connection of said module or combination of modules to one or more amplifier signal output connections. Equally so as is the case for the modular amplifier according to the invention, the assembly is able to assign a requested amplification power to each signal entering the amplifier assembly, in combination with monitoring the actual power available amplification power of each module the controller unit and/or algorithm are configured for selectively forming groups of one or more amplifier modules that have the requested power of a respective signal available. In fact, the assembly allows for even more combinations of amplifier modules since it is not limited to the modules in a single amplifier, but the assembly is also allowed to group amplifier modules in different modular amplifiers.

Yet in a different embodiment the controller unit of the amplifier assembly and the controller of the amplifier together form an overall controller, said overall controller configured for; selecting, out of all available modules, one or more groups of modules, thus forming one or more virtual amplifiers. Forming an overall controller can be achieved in two ways. First of all, the controller of the amplifier and the controller unit of the assembly can be configured to mutually communicate, resulting in an overall controller. Secondly, it is very much likely that the controller of the amplifier and the controller unit of the assembly are in fact one and the same controller. By having an overall controller which is able to oversee all available amplifier modules the most effective control of the system is achieved. The overall controller is able to optimize the modules on the assembly level and also on the amplifier level. Doing so both the assembly and all separate amplifiers meet their threshold levels. That is, none of the inserted amplifiers are operating beyond their efficiency level, since the overall controller is configured to continuously monitor all modules. Moreover, the entire assembly is not operating beyond the efficiency level, since the controller is also configured for continuously monitoring the entire assembly as a whole. This can be furthermore elucidated as follows. The overall controller can be seen as a controller that detects a number of available amplifier modules, instead of detecting entire amplifiers, which occurs according to the state of the art. Even further, the overall controller is configured for freely forming, out of all of the detected amplifier modules, independent of the amplifier they are housed in, a virtual amplifier for amplifying a signal. Hence, the overall controller can form any number of groups of amplifier modules that are available, thereby forming a virtual amplifier that is configured for amplifying a signal with the combined amplifying power of said group of modules. By utilizing all modules the overall controller is able to form groups for amplifying signals with high amplification power, or groups of modules for amplifying signals with low amplification power. This can also occur simultaneously, such that a signal is amplified with a high power at the same time another signal is amplified with a low power, each by a different group of modules.

In a different embodiment of the assembly according to the present invention the algorithm is predetermined or comprises artificial intelligence. Since the controller operates based on the algorithm it basically operates based on the predetermined algorithm or the artificial intelligence algorithm due to dependency. The artificial intelligence network can utilize all data acquired by the controller. For example, if an input signal is received, the controller and/or algorithm might compare the signal to previous signals received, and if the signal corresponds to one of the previous signals, use the same strategy, or an improved strategy to allocate amplifier modules. The assembly might be further configured for manually feeding data to the assembly. Such data might comprise for instance information regarding an artist that is currently playing. The algorithm can utilize its datapool collected during previous events of the same artist if available, and anticipate for instance on expected volume changes, audience response and the like. The artificial intelligence network learns from previous use of the system anywhere on the world, any behavior of public, the volume, type of music playing, positions of the speakers weather conditions and the like. As long as a change in the system affects the performance and thereby the usage of the modules, said change can be used in the future by the artificial intelligence network.

In yet another embodiment the controller unit is further configured for; allowing the inserted modular amplifiers to mutually communicate through the controller unit. This could increase the speed at which the assembly can reallocate modules. Also in case of a defect this could be detected and/or predicted earlier and can be anticipated upon. That means, the more amplifiers according to the present invention are used, the better the controller unit is able to predict failures or defects.

In again another embodiment all the inserted amplifiers have a mutual central hardware clock. This allows the amplifiers to be synchronised all the time, which prevents timing differences between the amplified signals. Timing differences are undesired since the could lead to disturbed sound, resonances in the venue and be in general unpleasant for the audience and/or the artist that is performing.

In an alternative embodiment the controller unit is configured for; directing the signals to the inserted amplifiers, such that each signal travels substantially the same pathlength from input to output, preventing mutual delays between signals. This furthermore allows the system to prevent for timing differences between signals.

In again a different embodiment the system comprises a converter, for converting the digital signal into an analog signal. The converter can be placed either right after the assembly signal input, such that the digital input signal is directly converted into an analog signal, which is then directed to the amplifiers. Otherwise, the assembly might also be provided with a plurality of converters, each being positioned right before an amplifier, such that upon entering an amplifier the digital signal is converted into an analog signal. Lastly, the converter might also be positioned in the amplifier itself, right before the signal enters the amplification modules. By using converters in the assembly the need for an external converter is eliminated, allowing the user to directly couple digital output signals to the assembly.

Again in a different embodiment the controller unit is configured to; redirecting a requested amplification power over the available amplifier modules if a hardware failure occurs in the assembly. If failure is detected and/or predicted, which might be just a temporal overshoot in for example temperature, the assembly is able to redirect the signal over different modules such that none of the signals gets lost. The term failure should however be interpreted broadly, and does not necessarily mean a hardware failure. Other types of failures should also be included such that at all times a proper operation of the assembly is ensured. To this end the assembly can in general be equipped with a back-up controller unit, which receives the exact same information as the controller unit, only to be utilized in the event the controller has a failure.

In yet another embodiment the common power unit is configured for; converting a power supplied to the assembly into a power required by the inserted amplifiers, wherein the controller unit is further configured for; pre-loading at least one capacitor of the common power unit and/or module. By preloading capacitors the assembly is able to prevent overshoots in power requests. That is, peaks in the power consumption can be equalized by the system by means of preloading capacitors. This reduces the demand on the power network, and also prevents the internal power connections from overloading, or not being able to meet volume requests. The assembly can be equipped with thinner cables since the peak loads are flattened over a longer period of time. The assembly is however not limited to preloading capacitors of the common power unit, but any capacitor in the system might be used if suitable to this end. The controller might in a different embodiment even be configured for preloading the capacitors based on the music that is currently playing. If the signal is analysed, and a certain part of the signal requires a significantly higher amplification power, the controller unit can preload the capacitors such that at the time the certain part of the signal is to be amplified the preloaded capacitors can be used. Also the style of the music, previous performances of the same artist, or sound recognition can be used for determining whether preloading the capacitors is required. Flattening the power consumption peaks over time is not only applicable for audio signals, but can also be used to drive an intelligent PSU (Power Supply Unit) for multiple computer systems. Based on expected activity (either learned (AI/Machine Learning) from the past or actively/manually set) capacitors or even battery stacks could be loaded during low- power moments. When a system, based on multiple computer systems controlling amplifier activity or other applications uses this technique a more effective distribution network with less overdimensioning in peak capacity requirements may be provided.

In yet another embodiment the controller unit is configured for; continuously monitoring the instantaneous power of each module, and redirecting the requested amplification power based on the algorithm. This allows the system to continuously reallocate the signals such that none of the amplifier modules are utilized above their maximum efficiency operating point.

In the state of the art amplifiers comprise typically a solid connection between the amplifier output and the speaker input. Hence, one has to physically adapt if a change is required. In these systems a digital audio signal is converted into analog signal by means of a signal converter. The analog signal can subsequently be amplified by the amplifier, which increases the amplitude of the signal to a predefined value that corresponds with a manually and/or digitally set desired amplification value. The amplified signal then has to be distributed towards, in most cases, a speaker. In general it is known to directly couple a single speaker to an amplifier. However, one can also connect a plurality of speakers to an amplifier. Moreover, it would even be possible to connect a plurality of speakers to a plurality of amplifiers. Such connections are in general predefined, and made up manually during the set-up. This is often the case in concert halls, or festival venues. The speakers are installed before the event, are all connected to amplifiers according to the wishes of an audio specialist who determines which amplifier should be connected to which one or more speakers. After installing, the connections are solid, that is, in the light of the invention, predefined and non-adaptable. However, such solid connections between amplifier outputs and speaker inputs are undesirable because of multiple reasons. First of a the usage of the amplifiers is very limited. If a signal is directed to an amplifier, this implicitly means the signal is directed towards a predefined speaker to which said amplifier is connected. Moreover, if an amplifier should break down, an entire portion of the venue will lose its speaker output due to the solid connection between the broken amplifier and the connected speakers. Also, since all connections are placed manually, errors are easily introduced given the complex electronic lay-outs on festival venues. This might lead to unpleasant sounds in the music for the people visiting the festival. Although switching arrays are known in the lower power spectrum, it tends to be difficult to implement said type of switching arrays in high power applications. In high power applications it is particularly difficult to suppress the disturbances and leakage of the signal. Leakage or disturbance may cause a hum-tone or hearable tone when switching or combining higher power signals, which is undesired in the case of venue speaker sets, since the audience may be able to hear the hums and sounds caused by the disturbed and/or leaked signals. The present invention is in particular related to switching analog, high-power, variable frequency, alternating currents of amplified signals. Preferably amplified audio (speaker) signals, but optionally also AC-power signals. The present invention is in particular not related to routing low power signals.

Various MOSFET technologies (Si, SiC, GaN) have relatively high power density and can switch voltages up to 1200V and currents in excess of 200 A in a 1 cm2 package. When the switched signal is AC, though, there are multiple challenges involved: MOSFETs are designed to switch DC currents only. When the signal is AC, either two MOSFETs in back-to-back configuration are required or different components are used such as Triacs. Triacs, however, work only at low frequencies. Thus, they may be used to switch AC mains voltages at 50/60 Hz, but this did not prove to be suitable for applications of high power and high frequencies, such as amplified audio signals or radar signals or microwave signals. When the switched signal is medium frequency (multiple kHz) such as in audio or high frequency (multiple MHz and GHz) such as in telecommunications and radar, the only viable solid state switching solution is the MOSFET transistor.

One disadvantage for MOSFETs is that the metal-oxide isolated gate acts as a capacitor. Thus, MOSFETs cannot switch AC signals completely OFF. Hence, there will be a leakage across the FET gate-drain or gate-source connections. Typical output capacitance for Silicon Carbide (SiC) MOSFETs is in the range of 267 pF, which represents relatively low impedance at high audio frequencies of 20 KHz which may cause the audio signal to leak across the switch in an OFF configuration of the MOSFET and contaminate other signals in the system. The common technologies for providing an ideal switch, i.e. one that is free of leakage in OFF state are not capable of switching high power AC signals.

It is therefore a goal of the present invention to allows for a more modular and reliable connection between input connectors and output connectors, or at least provide an alternative.

The present invention achieves this goal by Device for selectively connecting at least one audio input connector with at least one audio output connector, comprising, a number of (N) audio input connections, each for receiving an audio signal, a number of (M) audio output connections, each for outputting an audio signal, a number of N×M switches, each for controllably electrically connecting a unique combination of an input connection with an output connection, a plurality of relays, each for controllably electrically connecting a unique combination of an input connection with an output connection, a controller, for controlling the N×M switches, and the plurality of relays, wherein the audio input and output connections and the switches are dimensioned for connecting respectively an amplified audio signal of at least 90 W and preferably at least 100 W, the switches are formed by MOSFETs, the controller is configured to control the MOSFETs and the plurality of relays based on control data. The power of the amplified audio signal is however not limited, and the device according to the present invention is capable of handling a power of up to, but not limited to, 240 kW, wherein each switch can handle a power up to, but not limited to, around 60 kW.

The device according to the present invention allows for a quickly adaptable connection between input connectors and output connectors. The input connectors of the device are in general connected to one or more amplifiers. The output connectors of the device are in general connected, either directly or indirectly, to one or more speakers. However, the device is also suitable for use in any situation where input connectors should be connected to output connectors, and where the signal to be switched is one of high power and alternating current. The invention is in particular related to situations wherein there are a plurality of input connectors and a plurality of output connectors, wherein there shall be made an electronic connection between at least one input connector and at least one output connector. That is, preferably without contamination of the signal. For example, a signal from input “a” that should only be directed to output “b” should preferably not contaminate any other output connections. Contaminating other output connections may be understood as for example a portion of the signal leaking through to the other output connections. In particular when dealing with amplified audio signals, a leakage of the signal to the wrong output connection of around 5% of the nominal signal value would already be at an audible level. Hence, this leakage of the signal will contaminate any audio that is directed to a speaker connected to output “b”. This is an undesired result that the present invention intends to solve, or at least improve. Said electronic connection is made by a controller, which is able to selectively electronically connect one input connector and one output connector. This electronic connection is established by using a plurality of switches. Each of said switches can establish a connection between one input connector and one output connector. In particular, each switch establishes a unique connection, wherein the number of switches is preferable at least equal to the amount of unique combinations of connections between the input connectors and the output connectors. The present invention is related to switching audio signals, in particular amplified audio signals. These signals tend to be high power, demanding high-end quality of the components used. Therefore, all components used for creating the device according to the invention should be rated to withstand, preferably with a predefined margin, the power. The controller is configured to control the switches based on control data, which control data may comprise any information required to effectively connect the correct input connector with the correct output connector. Metal Oxide Silicon Field Effect Transistors (MOSFETs) are suitable switches for the current application. Any electronic component that is able to withstand the power of the signals used in the present application and is able to selectively form or release an electronic connection could be used. Examples of such switches are bipolar transistors, both N-type and P-type, MOSFETs, both N-type and P-type. Complementary pairs of MOSFETs could be used to create a switching circuit which consumes only a very low power, called Complementary MOS (CMOS) logic. Any switch could be used as long as the specifications are comparable to that of a MOSFET. It should be understood that, where a device is claimed, the components of said device could be placed inside a bigger device, such as for example an amplifier system. The device does therefore not necessarily have to be stand alone and could be part of a larger whole. For example MOSFETs can be used having a capacity of 650 V and 90 A. Alternatively, the device according to this aspect of the invention may be used for switching high power signals, other than audio signals. In particular for high power AC signals, the present invention may be used. To this end, the same components are used, only the input and output connections receive an high power AC signal, instead of an (amplified) audio signal. As such, static switching in other high-current or power AC-environments the device may be used whilst maintaining the same advantaged. That is, less leakage and contamination of signal(s), additionally a more compact way of switching may be realized. Typical non-audio applications may for example be power distribution units, in particular for high-current/power application, or power supply units of said high-current/power application.

It is conceivable that the device according to this aspect of the invention is implemented in the modular amplifier according to the invention. When combined, a modular amplifier housing comprising a plurality of amplifier units and a modular routing system provide a synergetic effect. That is, the signal may be amplified in the modular amplifier, optionally using the virtual amplifiers, and may directly be routed to desired output connections. To this end, the device for connecting input and output connections may be provided such that the outputs of the different amplifier output connections connect directly to the various audio signal input connections, and the various (M) audio signal output connections connect to the assembly signal output connections.

By applying said relay, it is possible to prevent excessive contamination of the signals. To this end, preferably each relay may be controllable such as to effectively route a signal. Preferably, the relay is provided such as to electrically bypass at least one switch. Bypassing at least one switch allows the present invention to reduce the contamination of the signals at the output connections. In particular the leakage of AC signal due to parasitic capacitance that causes a portion of a signal to unintentionally reach an undesired output connection may be reduced via the relay. Therefore the combination of switches, i.e. MOSFETS, and the relays allow for the present invention to effectively switch high power AC signals without excessive leakage of signals. Hence, in particular for amplified audio signals, this may result in a better production of sound from the speakers, especially since leakage of signal to the wrong speakers may be significantly reduced.

According to another embodiment of the present invention at least the input connections and/or the output connections are housed in one connector. By using a single connector for housing at least the input connections and/or the output connections an easy connection can be made between the device according to the present invention and the amplifiers and/or speakers to which the device is to be connected. It is furthermore conceivable that the device according to the present invention comprises a common connection board, which board is provided with the connector. The device could as such be insertable into a larger device such as an amplifier system. By sliding in the device it is connected to the amplifier assembly and can effectively connect the amplifiers to speakers easily.

In a different embodiment the controller is configured to receive the control data, either wired or wireless, and/or from a file and/or a memory and/or manual input by a user. Control data in the present application should be understood broadly. This could be any data that provides the controller enough information to establish a correct connection. The control data can be received by wire, for example by means of an additional connector for receiving control data. However the controller might also be configured to receive the control data wirelessly, by means of any wireless communication technology. Moreover, a user could provide a control file which comprises all required data to the controller using a manual input. This manual input could be in any form, such as a screen and keyboard or a touchscreen. However, the data might as well be provided automatically, based on information present in the system. Yet, it is also conceivable that any combination thereof is used. The controller could by default be configured in an automatic mode wherein the controller automatically controls the switches based on the control data. If also a touchscreen or memory location is available the user could, by means of manual input of control data, opt to overrule the automatic mode and take over the control by providing the required control data.

In a different embodiment at least one switch, preferably all switches are positioned on a common switchboard. By forming a common board all components can be easily mutually connected. The switchboard might in particular be formed by a printed circuit board, wherein all connections between the input connectors and the output connectors are embedded in the circuit board, the switches are configured for switching between the plurality of unique connections. It is also conceivable that the switchboard is a flexible electronic board, wherein the board is flexible moving, such that it is allowed to be positioned in tight spaces. Preferably, the printed circuit board provides capacity for high currents, preferably the printed circuit board comprises a multi-layer path for conducting electricity. Where normally for high currents applications heavy copper traces, that is relatively wide (around 1 to 5 mm) and relatively thick (around 1 to 2 mm), are used, the present invention provides for a plurality of parallel traces. The traces may be provided in different layers of the printed circuit board, preferably at least 4 parallel traces are provided, preferably at least 8 parallel traces. The plurality of parallel traces are preferably parallel with respect to the printed circuit board. This allows the present invention to maintain a tight level of manufacturing clearances for fine pitch components provided on the same printed circuit board.

Preferably each of the plurality of thin parallel traces has a thickness of at most 0.5 mm, preferably at most 0.25 mm more preferably at most 0.1 mm parallel, wherein thickness is understood to be the direction perpendicular to the printed circuit board. This allows to place both high current and low current components on the same circuit board. Since traces in a single layer of the circuit board may only be printed at one specific thickness per layer, it is not possible to provide for accurate production of both high current and low current components. The high current components require a trace thickness of around 1 to 2 mm, and a width around 1 to 5 mm to be able to receive the amount of current. An integrated circuit on said circuit board may have a pitch of only 0.2 mm, which yields traces of 1 or 2 mm thick (since only one thickness of traces per layer may be printed), with a width of around 0.2 mm which would be highly unstable on their bottom sides. Hence, the low current components are to be provided on unstable trances, which at their bottom potentially collapse, or locally thickening, due to the weight of the trace and may cause shortage of the circuit. Therefore, by providing a plurality of thin parallel traces in different layers of the circuit board, this problem may be circumvented. For example, a total of 4 parallel traces in different layers each of 0.25 mm thickness may be provided. By connecting all traces parallelly to the high current component, it may receive the current required, whereas, only a single of said four parallel layers, preferably the top layer, may be used for providing current to the low voltage components, and since the trace for said low current IC is now of a cross sectional dimension of 0.25×0.2 mm it is less prone to the previously mentioned instabilities.

The low voltage components may for example be (micro) diodes, or resistors, MPU's, Drivers, IC's with a small pitch, or capacitors.

In a different embodiment the control data comprises at least a predetermined output connection related to the at least one audio signal received by at least one input connection, wherein the controller is further configured for controlling the MOSFETs such that the at least one input connection receiving the at least one audio signal is electrically connected to the predetermined output connection. Using a predetermined output as control data the controller is able to timely and selectively establish the desired connection between the desired input and output connectors. The predetermined output connections should therefore however be related to a certain input audio signal, such that the controller can control the MOSFETs such that the correct MOSFET is provided with a power in order to make a connection between the input connector where said audio input signal arrives, and the predetermined audio output connector.

In again a different embodiment the electrical pathlength between each input connection and output connection are substantially equal in length, such that mutual delays in signals are prevented. Doing so prevents that the time a signal has to travel from an input connector to an output connector will always be substantially identical. Timing delays between audio signals can result in very unpleasant situations, very much so in high volume venues. One can also realize this effect by means of software delays for certain signals which travel a shorter electronic distance, however ensuring substantially equal electronic pathways is easier. To this end the device may comprise a common hardware clock, such that in the case one signal still arrives marginally earlier or later with respect to a predetermined timing, software delays can be employed to said signal to counteract for the delay. Pathlengths of the connections between the input and output can be either manually computed or by the use of one of many circuit board design software packages.

In yet another embodiment the device is adapted for simultaneously electrically connecting at least two input connections with at least two output connections, for connecting at least two input audio signals. It is beneficial when the device is adapted to arrange multiple signals selectively at once. The device is thus configured to simultaneously establish an electrical connection between a first input connector and a first output connector and between a second signal input connector and a second signal output connector. The device is however not limited to this number, and can in fact simultaneously arrange an arbitrary number of input signals.

In a different embodiment the device further comprises a cooling system, for cooling the switches. The switches, in particular MOSFETs tend to heat up due to internal inefficiencies. These inefficiencies are caused by parasitic capacitances. The parasitic capacitances can be contemplated as a parameter that limits the frequency at which the MOSFET can operate and limit the switching speed. The drain and source of a MOSFET are typically insulated from the gate through a so called gate oxide film. In general three parameters relate to the parasitic capacitances, being the input capacitance, output capacitance and the feedback capacitance. The input capacitance is equal to the gate source capacitance and the gate drain capacitance together. The output capacitance is equal to the drain source capacitance and gate drain together, whereas the feedback capacitance is equal to the gate drain capacitance. These parameters depend typically on the drain source voltage. Generally the feedback capacity has the biggest influence on the switching speed of the MOSFET. If the MOSFET switches relatively slow, or there is a significant voltage drop over the MOSFET they heat up. This heat has to be removed since it could potentially do damage. Therefore a cooling system is used to cool down the MOSFETs. The cooling system could be of any kind, such as liquid cooling or gaseous cooling.

In a different embodiment the device further comprises a cooling system, for cooling the connector. Since a lot of high power connectors are positioned closed to one another, heat tends to build up in this region. A cooling system is applied to cool down the connector such that it operates at an allowable temperature.

In yet again a different further embodiment the cooling system is a common cooling system, for cooling the switches and the connector simultaneously. A common cooling system could cool both the connector as well as the MOSFETs using custom circuitry of coolant.

In a different embodiment the number of N×M switches are in particular 32×32 switches, more in particular 64×64. The number of switches is chosen based on the number of in and output connectors that have to be mutually connected. However, the number of switches is not limited to this number, when a Field Programmable Gate Array is used, the numbers N and M can be arbitrarily chosen according to the desired amount of connections and possibilities. Therefore, the amount of switches depend on the technique used and the requirements of the system.

Preferably at least one audio input connection, preferably all audio input connections, is connected to a plurality of, preferably each of the (M) audio output connection via a plurality of H-beam or I-beam circuits, in particular via (M) H-beam or I-beam circuits, each H-beam or I-beam circuit comprising at least four switches, and at least one relay. This allows a high level of flexibility to which the switches and relay may be used. As such, the switches and relay may, by the controller, be arranged such that the signal from the input connection is only connected to the designated output connection, wherein the output connections to which the signal should in particular not be designated, are preferably shorted via the at least one relay. It is preferred that each audio signal input connection is connected via one H-beam or I-beam circuit, each comprising at least one relay, for each of the signal output connections. Hence, if there are N input connections, and M output connections, preferably each of the N input connections comprises at least M H-beam or I-beam circuits, each provided with at least one relay. Preferably, the maximum leakage over switches is less than 5% of the nominal signal, more preferably less than 3% of the nominal signal value, more preferably less than 1% of the nominal signal value.

Preferably, the at least one relay of at least one H-beam or I-beam circuit is at opposing sides electrically connected to two switches. More preferably, the two switches on either side of the relay are preferably serially connected, wherein said relay connects in the middle of said two switches at either side of the relay. This allows the device to bypass switches, i.e. MOSFETs, that are in OFF state for a specific signal, and hence preventing the leakage of signal over the FET gate-drain or gate-source connections of the MOSFETs in their OFF state. Preferably, in the OFF state, a leakage over a MOSFET is less than 5% of the nominal signal power value, preferably less than 3% of the nominal signal value, more preferably less than 1% of the nominal signal value. If the leakage is below or around 1% of the nominal signal power value, the noise contamination towards the undesired output connections will most likely not be audible, and hence will in a festival venue not cause any undesired noises or sounds through certain speakers.

Preferably the switches and relay of at least one H-beam or I-beam circuit, preferably each H-beam or I-beam circuit, are independently controllable. By independently controlling each of the switches and relays, a maximum amount of flexibility may be achieved. For example, various different input signals from the input connections may effectively be distributed to different output connections. For example, two or three input connections may receive the same signal, which is, by each of the input connections, simultaneously distributed to a single output connection. Also, two input connections may receive the same amplified AC signal, and one input connection receives a different amplified AC signal, it is possible to route said two similar amplified AC signals to a single output connection, and routing said different amplified AC signal to a different output connection using the same device. Although in this respect merely two examples are provided, the present invention is not limited thereto, in face any number of input connections may be uniquely connected to output connections. Moreover, any amount of signals may be distributed as desired, that is combined or separately. This may prevent the need for complex cables which tend to be required on festival venues and the like in order to connect a plurality of amplifiers to a plurality of speakers. Using the device according to the invention, a greater degree of flexibility, without loss of sound quality may be achieved.

Preferably, a resistance of the relay is lower than a resistance of the at least four switches. By providing a relay that has a resistance lower than that of the switch (i.e. MOSFET) the signal may be effectively and efficiently routed away from a switch through which signal may potentially leak. This allows to be sure that the signal in fact travels through the relay instead of leaking through the OFF state MOSFET, and causing a leaked signal.

The present invention is further related to a method for selectively connecting at least one audio input connector with at least one audio output connector, comprising the steps of a) receiving at least one audio signal, wherein the at least one audio signal is received on at least one of (N) audio input connections, b) determining at least one output connection out of a number of (M) audio output connections, to which the at least one audio signal is to be connected, c) using a combination of N×M switches, said switches for controllably electrically connecting a unique combination of an input connection with an output connection, d) controlling, based on an input signal, the switches for selectively establishing a connection between the at least one input connection that received an audio signa and the at least one determined output connection. Using the method according to the present invention yields the same benefits as those gained from the device according to the invention. The benefits related to the device according to the present invention are therefore incorporated by reference with respect to the method.

In a different embodiment of the method according to the invention the switches are formed by MOSFETs, and wherein step d) comprises controlling the MOSFETs. MOSFETs are suitable since they are compatible with high power signals and switch at a high frequency. In a different embodiment according to the method use is in particular made from the device according to any embodiment of the present invention.

Preferred embodiments of the present invention are set out in the following non-limitative clauses.

### CLAUSES

1. Modular amplifier comprising;
   an amplifier housing, said housing provided with;
   an amplifier power input connection,
   at least one amplifier signal input connection for receiving at least one input signal to be amplified,
   at least one amplifier signal output connection, for delivering at least one amplified signal;
   a plurality of amplifier modules, each module comprising:
   a module power connection coupled to the amplifier power input connection;
   a module signal input connection;
   a module signal output connection;
   amplification hardware, having an amplifying power;
   a controller, configured for:
   selectively connecting, based on an algorithm, the at least one amplifier signal input connection to one or more module signal input connections of amplifier modules, for amplifying the at least one input signal to be amplified, and
   connecting the module signal output connection of said one or more amplifier modules to one or more amplifier signal output connections.
2. Modular amplifier according to clause 1, wherein the algorithm comprises the step of;
   receiving a requested amplification power related to the at least one input signal to be amplified
   monitoring an available amplification power of each module,
      and wherein the algorithm further comprises the step of;
   determining, based on the requested amplification power and/or available amplification power of each module, if one amplifier module or a combination of amplifier modules has the requested power available.
3. Modular amplifier according to any of the preceding clauses, wherein the at least one amplifier signal input connection is configured for simultaneously receiving a plurality of signals to be amplified, or wherein the amplifier comprises a plurality of amplifier signal input connections, each for receiving one signal to be amplified,
wherein the controller is further configured for;
   selectively forming, based on the algorithm, a plurality of one or more amplifier module groups, each for amplifying a signal, forming one or more virtual amplifiers.
4. Modular amplifier according to clause 3, wherein the algorithm comprises the step of;
   receiving, for each signal, a requested amplification power
   monitoring an available amplification power of each module,
      and wherein the algorithm further comprises the step of;
   determining, based on the requested amplification power and/or available amplification power of each module and each signal, if the one or more amplifier module groups has the requested power available.
   selectively connecting the at least one amplifier signal input connection to the module signal input connections of the determined one or more amplifier module groups having the power available, and connecting the module signal output connection of said one or more amplifier module groups to one or more amplifier signal output connections.
5. Modular amplifier according to any of the preceding clauses, wherein the controller is further configured for;
   determining if an actual performance of at least one amplifier module is exceeding a predetermined performance threshold value,
   if at least one amplifier module is exceeding the threshold value, assigning an additional amplifier module to the signal, such that preferably all amplifier modules assigned to the signal meet the performance threshold value,
   if all amplifier modules are operating at their performance threshold value, equally dividing the request over all amplifier modules.
6. Modular amplifier according to clause 5, wherein the performance threshold value is chosen from the group consisting of;
   an actual power of a module;
   a temperature of a module;
   frequencies available in the signal;
   moisture inside the amplifier.
7. Modular amplifier according to any of the preceding clauses, wherein the at least one amplifier signal input connection is configured for;
   receiving a composed signal,
   decomposing the received composed said composed signal into a plurality of signals to be amplified.
8. Modular amplifier assembly, comprising;
   an assembly housing, said housing provided with;
   at least one assembly signal input, for receiving at least one signal to be amplified,
   at least one assembly signal output, for delivering at least one amplified signal;
   a common power unit, for delivering a power to the assembly,
   a plurality of slots, each slots configured for receiving a modular amplifier according to any of the clauses 1-7, wherein each slot comprising;
   a power connector, connected to the common power unit on one end and the amplifier power input connection of an inserted amplifier on the other end, for powering the inserted amplifier,
   a signal input connector, connected to the assembly signal input on one end, and the at least one amplifier signal input connection of an inserted amplifier on the other end, for providing the inserted amplifier with at least a portion of the least one signal to be amplified,
   a signal output connector, connected to the assembly signal output on one end, and the at least one amplifier signal output of an inserted amplifier on the other end, for delivering an amplified signal,
   a controller unit, wherein the controller unit is configured for;
   selectively forming, based on the algorithm, one or more amplifier module groups, wherein said groups are formed out of one or more inserted amplifiers, forming one or more virtual amplifiers, and
   connecting the one or more amplifier signal output connections to the one or more assembly signal output connections.
9. Modular amplifier assembly according to clause 8, wherein, the controller unit is further configured for;
   receiving a requested amplification power related to the at least one input signal to be amplified,
   monitoring an available amplification power of each module,
      and wherein the algorithm comprises the step op;
   determining, based on the requested amplification power and/or available amplification power of each module, if one amplified module or a combination of amplified modules has the requested power available,
   selectively connecting the at least one amplifier signal input connection to the module signal input connections of the determined module or combination of modules having the power available, and connecting the module signal output connection of said module or combination of modules to one or more amplifier signal output connections.
10. Modular amplifier assembly according to any of clauses 8-9, wherein, the controller unit of the amplifier assembly and the controller of the amplifier together form an overall controller, said overall controller configured for;
   selecting, out of all available modules, one or more groups of modules, thus forming one or more virtual amplifiers.
11. Modular amplifier assembly according to any of clauses 8-10, wherein the algorithm is predetermined or comprises artificial intelligence.
12. Modular amplifier according to any of clauses 8-11, wherein the controller unit is further configured for;
   allowing the inserted modular amplifiers to mutually communicate through the controller unit.
13. Modular amplifier assembly according to any of the clauses 8-12, wherein all the inserted amplifiers have a mutual central hardware clock.
14. Modular amplifier assembly according to any of the clauses 8-13, wherein the controller unit is configured for;
   directing the signals to the inserted amplifiers, such that each signal travels substantially the same pathlength from input to output, preventing mutual delays between signals.
15. Modular amplifier assembly according to any of the clauses 8-14, wherein the system comprises a converter, for converting the digital signal into an analog signal.
16. Modular amplifier assembly according to any of the clauses 9-15, wherein the controller unit is configured to;
   redirecting a requested amplification power over the available amplifier modules if a hardware failure occurs in the assembly.
17. Modular amplifier assembly according to any clauses 8-16, wherein the common power unit is configured for;
   converting a power supplied to the assembly into a power required by the inserted amplifiers,
wherein the controller unit is further configured for;
   pre-loading at least one capacitor of the common power unit and/or module,
18. Modular amplifier assembly according to any of the clauses 8-17, wherein the controller unit is configured for;
   continuously monitoring the instantaneous power of each module, and
   redirecting the requested amplification power based on the algorithm.
19. Device for selectively connecting at least one, preferably audio, input connector with at least one audio output connector, comprising:
   a number of (N), preferably audio, input connections, each for receiving a signal, preferably an audio signal;
   a number of (M), preferably audio, output connections, each for outputting a signal, preferably an audio signal;
   a number of N×M switches, each for controllably electrically connecting a unique combination of an input connection with an output connection;
   preferably a plurality of relays, each for controllably electrically connecting a unique combination of an input connection with an output connection;
   a controller, for controlling the N×M switches, and preferably the plurality of relays;
wherein
   the, preferably audio, input and output connections and the switches are dimensioned for connecting respectively, high power signal, preferably an amplified audio signal, of at least 90 W and preferably at least 100 W;
   the switches are formed by MOSFETs; and
   the controller is configured to control the MOSFETs based on control data.
20. Device according to clause 19, wherein at least the input connections and/or the output connections are housed in one connector.
21. Device according to any of the preceding clauses, wherein the controller is configured to receive the control data, either wired or wireless, and/or from a file and/or a memory and/or manual input by a user.
22. Device according to any of the preceding clauses, wherein at least one switch, preferably all switches are positioned on a common switchboard.
23. Device according to any of the preceding clauses, wherein the control data comprises at least a predetermined output connection related to the at least one audio signal received by at least one input connection,
wherein the controller is further configured for;
   controlling the MOSFETs such that the at least one input connection receiving the at least one audio signal is electrically connected to the predetermined output connection.
24. Device according to any of the preceding clauses, wherein the electrical pathlength between each input connection and output connection are substantially equal in length, such that mutual delays in signals are prevented.
25. Device according to any of the preceding clauses, wherein the device is adapted for simultaneously electrically connecting at least two input connections with at least two output connections, for connecting at least two input audio signals.
26. Device according to any of the preceding clauses, wherein the device further comprises a cooling system, for cooling the switches.
27. Device according to clause 20, wherein the device further comprises a cooling system, for cooling the connector
28. Device according to clause 26 and 27, wherein the cooling system is a common cooling system, for cooling the switches and the connector simultaneously.
29. Device according to any of the preceding clauses, wherein the number of N×M switches are in particular 32×32 switches, more in particular 64×64.
30. Device according to any of the preceding clauses, wherein at least one audio input connection, preferably all audio input connections, is connected to each of the (M) audio output connection via a plurality of H-beam or I-beam circuits, in particular via (M) H-beam or I-beam circuits, each H-beam or I-beam circuit comprising at least four switches, and at least one relay.
31. Device according to clause 30, wherein the at least one relay of at least one H-beam or I-beam circuit is at opposing sides electrically connected to two switches.
32. Device according to clause 30 or 31, wherein the switches and relay of at least one H-beam or I-beam circuit, preferably each H-beam or I-beam circuit, are independently controllable.
33. Device according to any of the clauses 30-32, wherein a resistance of the relay is lower than a resistance of the at least four switches.
34. Method for selectively connecting at least one audio input connector with at least one audio output connector, comprising the steps of
   a) receiving at least one audio signal, wherein the at least one audio signal is received on at least one of (N) audio input connections,
   b) determining at least one output connection out of a number of (M) audio output connections, to which the at least one audio signal is to be connected,
   c) using a combination of N×M switches, said switches for controllably electrically connecting a unique combination of an input connection with an output connection,
   d) controlling, based on an input signal, the switches for selectively establishing a connection between the at least one input connection that received an audio signa and the at least one determined output connection.
35. Method according to clause 34, wherein the switches are formed by MOSFETs, and wherein step d) comprises controlling the MOSFETs.
36. Method according to any of the clauses 34-35, wherein in particular use is made from the device as claimed in any of clauses 19-29.

The invention will hereinafter be further elucidated based on the figures, wherein;

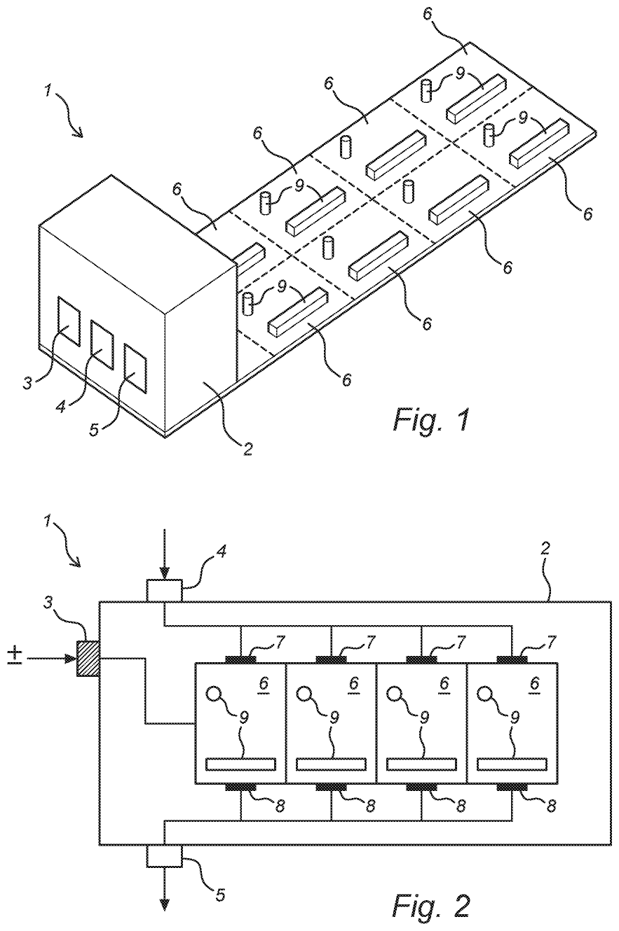

FIG. 1 shows a perspective view of a modular amplifier according to the invention;

FIG. 2 shows a schematic view of a modular amplifier according to the present invention, and;

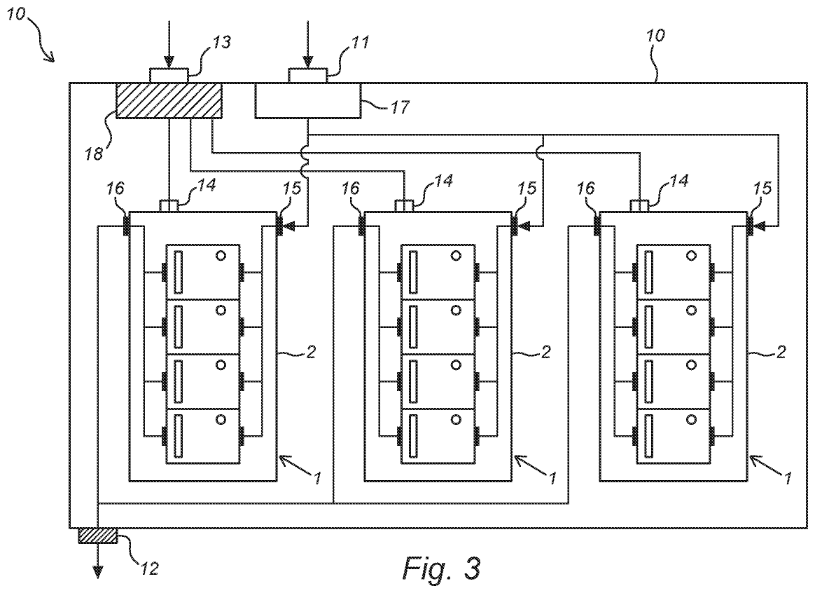

FIG. 3 shows a schematic view of an amplifier assembly according to the present invention comprising modular amplifiers as shown in FIG. 2.

FIG. 1 shows a perspective view of a modular amplifier 1 according to an embodiment of the present invention. The modular amplifier 1 has a housing 2, which is for illustrative purposes only partly shown in this figure. The back of the housing 2 comprises a number of connections 3, 4, 5. Although the connections are shown to be positioned on the back of the amplifier 1, these could even be positioned on the front or side of said amplifier 1. One of the connections 3, 4, 5, is in particular an amplifier power input connection 3. This connection is configured for delivering power to the entire amplifier 1. Furthermore an amplifier signal input connection 4 and an amplifier signal output connection 5 are present. These are respectively for receiving at least one signal to be amplified and transfer said signal to the amplifier 1 and for delivering an amplified signal. The connections 3, 4, 5 for power, an input signal and amplified output signal are shown as single connections. However, it must be understood that there might be multiple signal input connections 4 for each receiving a single signal to be amplified. Equally so for the signal output connection 5, of which multiple could be present wherein each would thus be configured for delivering an amplified signal. It is furthermore possible to include a communication connector (not shown), such as a communication bus or including ethernet connection. All connectors may also be housed in a common connector. Inside the amplifier housing 2 (only partly shown) there is a plurality of amplifier modules 6. Each of said modules 6 is configured for amplifying at least a part of a signal. To this end, each module 6 is provided with a module power connection (not shown), for receiving power from the amplifier power input connection 3. Furthermore, a module signal input 7 and module signal output 8 connection are provided, such that each modules can receive a signal that is received by the amplifier signal input connection 4. The module signal output connection 8 delivers an amplified signal to the at least one amplifier signal output connection 5. In order to amplify signals, the modules are each provided with amplification hardware 9, wherein the amplification hardware 9 has a predetermined amplifying power. The amplifier 1 according to this figure shows 8 separate modules 6 for amplifying. However, the number of modules 6 shown in this figure is merely illustrative, and in fact any number of modules 6 can be incorporated in the amplifier housing 2.

FIG. 2 shows a more schematic representation of the amplifier 1. It shows that the amplifier signal input connection 4 is connected to all of the module signal input connections 7, such that the controller can selectively connect the correct amplifier module 6. Only a single amplifier signal input connection 4 is shown in this figure, which could either receive a single analog signal, or a composed analog signal, wherein the composed analog signal should be decomposed before entering the respective module 6 assigned by the controller.

FIG. 3 schematically shows a plurality of amplifiers 1 as shown in FIG. 2 inserted into an amplifier assembly 10. The amplifier assembly 10 comprises at least one assembly signal input 11, which receives at least one signal to be amplified, and is configured for sending said signal to one or more amplifiers 1. The assembly 10 comprises at least one assembly signal output 12 for delivering at least one amplified signal. Also, the amplifier assembly 10 is provided with a common power unit 13 for powering all inserted amplifiers 1. The assembly 10 has a plurality of slots (not shown) which are adapted to each receive a modular amplifier 1 according to the invention. The figure merely illustrates the connections between the components. In fact, the slots are provided with a power connector 14, wherein after the amplifier 1 is slid into the slot the power input 3 of the amplifier 1 is coupled to the common power unit 13, such that the amplifier 1 is provided with power. Also the slots comprise each a signal input and output connector 15, 16, wherein after the amplifier 1 is slid into the slot, a connection is established between the assembly signal input 11 and the amplifier signal input 4, and between the assembly signal output 12 and the amplifier signal output 5. The common power unit 13 is connected, via station 18, to all the inserted amplifiers 1 separately. The station 18 in fact configured for converting a power supplied to the power connector 13 into a power required by each amplifier. Since not all amplifiers 1 have to be loaded equally, this required power can vary. In this non limitative embodiment the assembly 10 comprises a bus 17, which is configured for directing the assembly input signal which is received by the assembly signal input 11 to the correct amplifier 1. The assembly 10 shows a total of three inserted amplifiers 1, which is only for illustrative purposes, and can in fact be any number. Each amplifier 1 is drawn with a number of 4 amplifier modules 6. That means that for this non limitative figure a total number of 12 amplifier modules 6 are available. The controller unit is configured for selectively forming groups of amplifier modules 6, wherein each group can amplify a single signal received by the assembly signal input 11. This means, that the controller unit can form a maximum of 12 groups, each for amplifying a signal. However, it might also be the case that the first amplified is fully utilized by a single signal. And that the remaining two amplifiers together amplify two more signals, one signal amplified by 2 modules 6 for example, and the remaining six modules 6 amplifying the third signal. Any combination of modules 6 can be formed, and they do not have to be in a single amplifier 1.

1. Modular amplifier comprising;
an amplifier housing, said housing provided with;
an amplifier power input connection,
at least one amplifier signal input connection for receiving at least one input signal to be amplified,
at least one amplifier signal output connection, for delivering at least one amplified signal;
a plurality of amplifier modules, each module comprising:
a module power connection coupled to the amplifier power input connection;
a module signal input connection;
a module signal output connection;
amplification hardware, having an amplifying power;
a controller, configured for:
selectively connecting, based on an algorithm, the at least one amplifier signal input connection to one or more module signal input connections of amplifier modules, for amplifying the at least one input signal to be amplified, and
connecting the module signal output connection of said one or more amplifier modules to one or more amplifier signal output connections.

2. Modular amplifier according to claim 1, wherein the algorithm comprises the step of;
receiving a requested amplification power related to the at least one input signal to be amplified
monitoring an available amplification power of each module,
and wherein the algorithm further comprises the step of;
determining, based on the requested amplification power and/or available amplification power of each module, if one amplifier module or a combination of amplifier modules has the requested power available.

3. Modular amplifier according to any of the preceding claims, wherein the at least one amplifier signal input connection is configured for simultaneously receiving a plurality of signals to be amplified, or wherein the amplifier comprises a plurality of amplifier signal input connections, each for receiving one signal to be amplified,
wherein the controller is further configured for;
selectively forming, based on the algorithm, a plurality of one or more amplifier module groups, each for amplifying a signal, forming one or more virtual amplifiers.

4. Modular amplifier according to claim 3, wherein the algorithm comprises the step of;
receiving, for each signal, a requested amplification power
monitoring an available amplification power of each module,
and wherein the algorithm further comprises the step of;
determining, based on the requested amplification power and/or available amplification power of each module and each signal, if the one or more amplifier module groups has the requested power available.
selectively connecting the at least one amplifier signal input connection to the module signal input connections of the determined one or more amplifier module groups having the power available, and connecting the module signal output connection of said one or more amplifier module groups to one or more amplifier signal output connections.

5. Modular amplifier according to any of the preceding claims, wherein the controller is further configured for;
determining if an actual performance of at least one amplifier module is exceeding a predetermined performance threshold value,
if at least one amplifier module is exceeding the threshold value, assigning an additional amplifier module to the signal, such that preferably all amplifier modules assigned to the signal meet the performance threshold value,
if all amplifier modules are operating at their performance threshold value, equally dividing the request over all amplifier modules.

6. Modular amplifier according to claim 5, wherein the performance threshold value is chosen from the group consisting of;
an actual power of a module;
a temperature of a module;
frequencies available in the signal;
moisture inside the amplifier.

7. Modular amplifier according to any of the preceding claims, wherein the at least one amplifier signal input connection is configured for;
receiving a composed signal,
decomposing the received composed said composed signal into a plurality of signals to be amplified.

8. Modular amplifier assembly, comprising;
an assembly housing, said housing provided with;
at least one assembly signal input, for receiving at least one signal to be amplified,
at least one assembly signal output, for delivering at least one amplified signal;
a common power unit, for delivering a power to the assembly,
a plurality of slots, each slots configured for receiving a modular amplifier according to any of the claims 1-7, wherein each slot comprising;
a power connector, connected to the common power unit on one end and the amplifier power input connection of an inserted amplifier on the other end, for powering the inserted amplifier,
a signal input connector, connected to the assembly signal input on one end, and the at least one amplifier signal input connection of an inserted amplifier on the other end, for providing the inserted amplifier with at least a portion of the least one signal to be amplified,
a signal output connector, connected to the assembly signal output on one end, and the at least one amplifier signal output of an inserted amplifier on the other end, for delivering an amplified signal,
a controller unit, wherein the controller unit is configured for;
selectively forming, based on the algorithm, one or more amplifier module groups, wherein said groups are formed out of one or more inserted amplifiers, forming one or more virtual amplifiers, and
connecting the one or more amplifier signal output connections to the one or more assembly signal output connections.

9. Modular amplifier assembly according to claim 8, wherein, the controller unit is further configured for;
receiving a requested amplification power related to the at least one input signal to be amplified,
monitoring an available amplification power of each module, and wherein the algorithm comprises the step op;
determining, based on the requested amplification power and/or available amplification power of each module, if one amplified module or a combination of amplified modules has the requested power available,
selectively connecting the at least one amplifier signal input connection to the module signal input connections of the determined module or combination of modules having the power available, and connecting the module signal output connection of said module or combination of modules to one or more amplifier signal output connections.

10. Modular amplifier assembly according to any of claims 8-9, wherein, the controller unit of the amplifier assembly and the controller of the amplifier together form an overall controller, said overall controller configured for;
selecting, out of all available modules, one or more groups of modules, thus forming one or more virtual amplifiers.

11. Modular amplifier assembly according to any of claims 8-10, wherein the algorithm is predetermined or comprises artificial intelligence.

12. Modular amplifier according to any of claims 8-11, wherein the controller unit is further configured for;
allowing the inserted modular amplifiers to mutually communicate through the controller unit.

13. Modular amplifier assembly according to any of the claims 8-12, wherein all the inserted amplifiers have a mutual central hardware clock.

14. Modular amplifier assembly according to any of the claims 8-13, wherein the controller unit is configured for;
directing the signals to the inserted amplifiers, such that each signal travels substantially the same pathlength from input to output, preventing mutual delays between signals.

15. Modular amplifier assembly according to any of the claims 8-14, wherein the system comprises a converter, for converting the digital signal into an analog signal.

16. Modular amplifier assembly according to any of the claims 9-15, wherein the controller unit is configured to;
redirecting a requested amplification power over the available amplifier modules if a hardware failure occurs in the assembly.

17. Modular amplifier assembly according to any claims 8-16, wherein the common power unit is configured for;
converting a power supplied to the assembly into a power required by the inserted amplifiers,
wherein the controller unit is further configured for;
pre-loading at least one capacitor of the common power unit and/or module,

18. Modular amplifier assembly according to any of the claims 8-17, wherein the controller unit is configured for;
continuously monitoring the instantaneous power of each module, and
redirecting the requested amplification power based on the algorithm.

19. Device for selectively connecting at least one audio input connector with at least one audio output connector, comprising:
a number of (N) audio input connections, each for receiving an audio signal;
a number of (M) audio output connections, each for outputting an audio signal;
a number of N×M switches, each for controllably electrically connecting a unique combination of an input connection with an output connection;
a plurality of relays, each for controllably electrically connecting a unique combination of an input connection with an output connection;
a controller, for controlling the N×M switches, and the plurality of relays;
wherein
the audio input and output connections and the switches are dimensioned for connecting respectively an amplified audio signal of at least 90 W and preferably at least 100 W;
the switches are formed by MOSFETs; and
the controller is configured to control the MOSFETs and the plurality of relays based on control data.

20. Device according to claim 19, wherein at least the input connections and/or the output connections are housed in one connector.

21. Device according to any of the preceding claims, wherein the controller is configured to receive the control data, either wired or wireless, and/or from a file and/or a memory and/or manual input by a user.

22. Device according to any of the preceding claims, wherein at least one switch, preferably all switches are positioned on a common switchboard.

23. Device according to any of the preceding claims, wherein the control data comprises at least a predetermined output connection related to the at least one audio signal received by at least one input connection,
wherein the controller is further configured for;
controlling the MOSFETs such that the at least one input connection receiving the at least one audio signal is electrically connected to the predetermined output connection.

24. Device according to any of the preceding claims, wherein the electrical pathlength between each input connection and output connection are substantially equal in length, such that mutual delays in signals are prevented.

25. Device according to any of the preceding claims, wherein the device is adapted for simultaneously electrically connecting at least two input connections with at least two output connections, for connecting at least two input audio signals.

26. Device according to any of the preceding claims, wherein the device further comprises a cooling system, for cooling the switches.

27. Device according to claim 20, wherein the device further comprises a cooling system, for cooling the connector

28. Device according to claims 26 and 27, wherein the cooling system is a common cooling system, for cooling the switches and the connector simultaneously.

29. Device according to any of the preceding claims, wherein the number of N×M switches are in particular 32×32 switches, more in particular 64×64.

30. Device according to any of the preceding claims, wherein at least one audio input connection, preferably all audio input connections, is connected to a plurality of, preferably each of the (M) audio output connection via a plurality of H-beam or I-beam circuits, in particular via (M) H-beam or I-beam circuits, each H-beam or I-beam circuit comprising at least four switches, and at least one relay.

31. Device according to claim 30, wherein the at least one relay of at least one H-beam or I-beam circuit is at opposing sides electrically connected to two switches.

32. Device according to claim 30 or 31, wherein the switches and relay of at least one H-beam or I-beam circuit, preferably each H-beam or I-beam circuit, are independently controllable.

33. Device according to any of the claims 30-32, wherein a resistance of the relay is lower than a resistance of the at least four switches.

34. Method for selectively connecting at least one audio input connector with at least one audio output connector, comprising the steps of
a) receiving at least one audio signal, wherein the at least one audio signal is received on at least one of (N) audio input connections,
b) determining at least one output connection out of a number of (M) audio output connections, to which the at least one audio signal is to be connected,
c) using a combination of N×M switches, and preferably a plurality of relays, said switches and relays for controllably electrically connecting a unique combination of an input connection with an output connection,
d) controlling, based on an input signal, the switches, and preferably the relays, for selectively establishing a connection between the at least one input connection that received an audio signa and the at least one determined output connection.

35. Method according to claim 34, wherein the switches are formed by MOSFETs, and wherein step d) comprises controlling the MOSFETs.

36. Method according to any of the claims 34-35, wherein in particular use is made from the device as claimed in any of claims 19-29.

37. Use of the device for selectively connecting at least one audio input connector with at least one audio output connector according to any of the claims 19-33 for controllably electrically connecting a unique combination of an input connection with an output connection of a power distribution unit or power supply unit, preferably a high power AC power distribution or supply unit.
